(19) United States
(12) Patent Application Publication
(10) Pub. No.: US 2012/0111401 A1
(43) Pub. Date: May 10, 2012

(54) SOLAR CELL AND METHOD OF MANUFACTURING THE SAME

(75) Inventors: Sung Koo KANG, Suwon (KR); Young Ah Song, Suwon (KR); Sung Il Oh, Seoul (KR); Byoung Jin Chun, Seoul (KR); Dong Hoon Kim, Seongnam (KR)

(73) Assignee: SAMSUNG ELECTRO-MECHANICS CO., LTD.

(21) Appl. No.: 13/190,961

(22) Filed: Jul. 26, 2011

(30) Foreign Application Priority Data
Nov. 10, 2010 (KR) 10-2010-0111733

(51) Int. Cl. H01L 31/02; H01L 31/0224

(52) U.S. Cl. 136/256; 438/98; 257/E31.124

(57) ABSTRACT

There are provided a solar cell and a method of manufacturing the same. The solar cell includes: a solar cell unit absorbing sunlight to generate electricity; a surface treatment layer formed on at least one of upper and lower surfaces of the solar cell unit by a condensation reaction of a compound having a functional group —Y having a lone pair and an alkoxy group —OR; and a metal electrode layer bonded to the functional group —Y having the lone pair of the surface treatment layer. The solar cell has excellent energy conversion efficiency.

### CROSS-REFERENCE TO RELATED APPLICATIONS

This application claims the priority of Korean Patent Application No. 10-2010-0111733 filed on Nov. 10, 2010, in the Korean Intellectual Property Office, the disclosure of which is incorporated herein by reference.

### BACKGROUND OF THE INVENTION

1. Field of the Invention

The present invention relates to a solar cell and a method of manufacturing the same, and more particularly, to a solar cell having excellent energy conversion efficiency, and a method of manufacturing the same.

2. Description of the Related Art

As the depletion of existing energy resources such as oil or coal has been expected, the interest in alternative energy to substitute for traditional energy resources has increased. Among alternative energy sources, a solar cell, which is a cell generating electrical energy from solar energy, is environmentally-friendly, uses infinite solar energy as an energy source, and has long lifespan.

The solar cell may be divided into an inorganic solar cell and an organic solar cell.

In the case of the inorganic solar cell, are provided a silicon solar cell, a compound semiconductor solar cell, and the like, and of these, the silicon solar cell has mainly been used.

A general silicon solar cell includes a semiconductor substrate having different types of conductivity, which are p type and n type, an emitter layer, and electrodes respectively formed on the substrate and the emitter layer. In this configuration, p-n junction is formed on an interface between the substrate and the emitter layer.

When sunlight is incident to the solar cell, electrons and holes are generated in the semiconductor doped with n type and p type impurities by photovoltaic effect. The electrons and the holes generated by the photovoltaic effect are respectively attracted toward an n type emitter layer and a p type substrate to be collected in the electrodes respectively electrically connected to the substrate and the emitter layer. The electrodes are connected to each other by a wire, thereby obtaining power.

The organic solar cell may be made of a complex of a conductive polymer, which is an electron donor material, and a C₆₀ derivative, which is an electron acceptor material. As the organic solar cell, a dye-sensitized solar cell having a form in which dye is adsorbed on a surface of a nanocrystal oxide particle or a glass/polymer solar cell have been provided.

In addition to the division of the solar cell, according to a material configuring the solar cell, the solar cell may be divided according to a structure thereof. In this case, the solar cell may be mainly divided into a wafer structure (a bulk silicon solar cell), a thin film structure (a compound solar cell, a silicon thin film solar cell, an organic polymer solar cell, and the like), and a photoelectrical chemical structure (a dye-sensitized solar cell).

The dye-sensitized solar cell has used a technology of adsorbing organic dye, which is a light absorbing layer, on a surface of a film having a maximized surface area using a nanomaterial. The dye-sensitized solar cell has high energy conversion efficiency similar to that of an amorphous silicon solar cell, and has a cheap manufacturing cost.

A principle of the dye-sensitized solar cell is as follows. When sunlight (visible light) is absorbed in the electrode of an n-type nanoparticle semiconductor oxide in which dye molecules are chemically adsorbed on a surface of the dye-sensitized solar cell, the dye molecules generate an electron-hole pair, and electrons are injected into a conduction band of the semiconductor oxide. The electrons injected into the electrode of the semiconductor oxide are transferred to a transparent conductive film through an interface between nanoparticles to generate a current. The holes generated in the dye molecule are reduced by receiving the electrons by an oxidation-reduction electrolyte, such that an operation process of the dye-sensitized solar cell is completed.

The energy conversion efficiency of the solar cell is about 15%, which is significantly lower than that of a power plant using other sources of energy such as is used in thermal power generation. After a monocrystalline silicon solar cell has been developed, research into a solar cell having high efficiency, such as a back electric field layer, or the like, has been continuously conducted.

### SUMMARY OF THE INVENTION

An aspect of the present invention provides a solar cell having excellent energy conversion efficiency, and a method of manufacturing the same.

According to an aspect of the present invention, there is provided a solar cell, including: a solar cell unit absorbing sunlight to generate electricity; a surface treatment layer formed on at least one of upper and lower surfaces of the solar cell unit by a condensation reaction of a compound having a functional group —Y having a lone pair and an alkoxy group —OR; and a metal electrode layer bonded to the functional group —Y having the lone pair of the surface treatment layer.

The surface treatment layer may be formed by a chemical bond of a hydroxyl group —OH existing on one surface of the solar cell unit and the alkoxy group —OR.

The functional group —Y having the lone pair may be an amino group, a mercapto group, an imidazole group.

The alkoxy group —OR may be an alkoxy group having a carbon number of 1 to 8.

The compound having the functional group —Y having the lone pair and the alkoxy group —OR may be Y—Si—(OR)₃, Y—Zr—(OR)₃, Y—Ti—(OR)₃ or Y—Al—(OR)₂.

Treatment for activating the hydroxyl group may be performed on at least one of the upper and lower surfaces of the solar cell unit.

The surface treatment layer may be a monomolecular layer.

The solar cell unit may include a light absorbing layer made of a monocrystalline silicon, a polycrystalline silicon, an amorphous silicon, or a mixture of a monocrystalline silicon and an amorphous silicon, a CuInSe₂, a CuCaInSe₂, a GaAs, or an organic material.

The metal electrode layer may be made of a metal paste.

The solar cell unit may include at least one of a back reflective electrode film and a front reflective electrode film.

According to another aspect of the present invention, there is provided a method of manufacturing a solar cell, including: preparing a solar cell unit absorbing sunlight to generate electricity; forming a surface treatment layer on at least one of upper and lower surfaces of the solar cell unit by a condensation reaction of a compound having a functional group —Y having a lone pair and an alkoxy group —OR; and forming a metal electrode layer on the surface treatment layer.

The surface treatment layer may be formed by a chemical bond of a hydroxyl group existing on one surface of the solar cell unit and an alkoxy group.

The surface treatment layer may be formed by a self-assembly monolayer, a Langmuir-Blodgett (LB) method, a Langmuir Schaefer (LS) method, a dip coating method, or a spin coating method.

The surface treating surface may be a monomolecular layer formed by a self assembly monolayer.

The functional group —Y having the lone pair may be an amino group, a mercapto group, an imidazole group.

The alkoxy group —OR may be an alkoxy group having a carbon number of 1 to 8.

The method of manufacturing a solar cell may further include, before the forming of the surface treatment layer, performing treatment for activating the hydroxyl group on at least one of the upper and lower surfaces of the solar cell unit.

The compound having the functional group —Y having the lone pair and the alkoxy group —OR may be Y—Si—(OR)₃, Y—Zr—(OR)₃, Y—Ti—(OR)₃ or Y−Al−(OR)₂.

The metal electrode layer may be made of a metal paste.

The metal electrode layer may be formed by a screen printing method, a gravure printing method, a flexographic printing method, an offset printing method, an inkjet printing method, or a roll-to-roll printing method.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional diagram schematically showing a solar cell according to one embodiment of the present invention;

FIG. 2 is a mimetic diagram schematically showing a forming process of a surface treatment layer according to an exemplary embodiment of the present invention;

FIGS. 3A and 3B are photographs of a solar cell surface showing a tape test result according to Comparative Example;

FIGS. 4A and 4B are photographs of a solar cell surface showing a tape test result according to Inventive Example;

FIG. 5 is a photograph of a surface of a solar cell sintered at 200° C. for 60 minutes according to Comparative Example, and FIG. 6 is a photograph of a surface of a solar cell sintered at 200° C. for 60 minutes according to Inventive Example; and

FIG. 7 is another photograph of a surface of a solar cell sintered at 200° C. for 60 minutes according to Comparative Example, and FIG. 8 is another photograph of a surface of a solar cell sintered at 200° C. for 60 minutes according to Inventive Example.

### DETAILED DESCRIPTION OF THE PREFERRED EMBODIMENT

Exemplary embodiments of the present invention will now be described in detail with reference to the accompanying drawings. The exemplary embodiments of the present invention may be modified in many different forms and the scope of the invention should not be limited to the embodiments set forth herein. Rather, these embodiments are provided so that this disclosure will be thorough and complete, and will fully convey the concept of the invention to those skilled in the art. In the drawings, the shapes and dimensions may be exaggerated for clarity, and the same reference numerals will be used throughout to designate the same or like components.

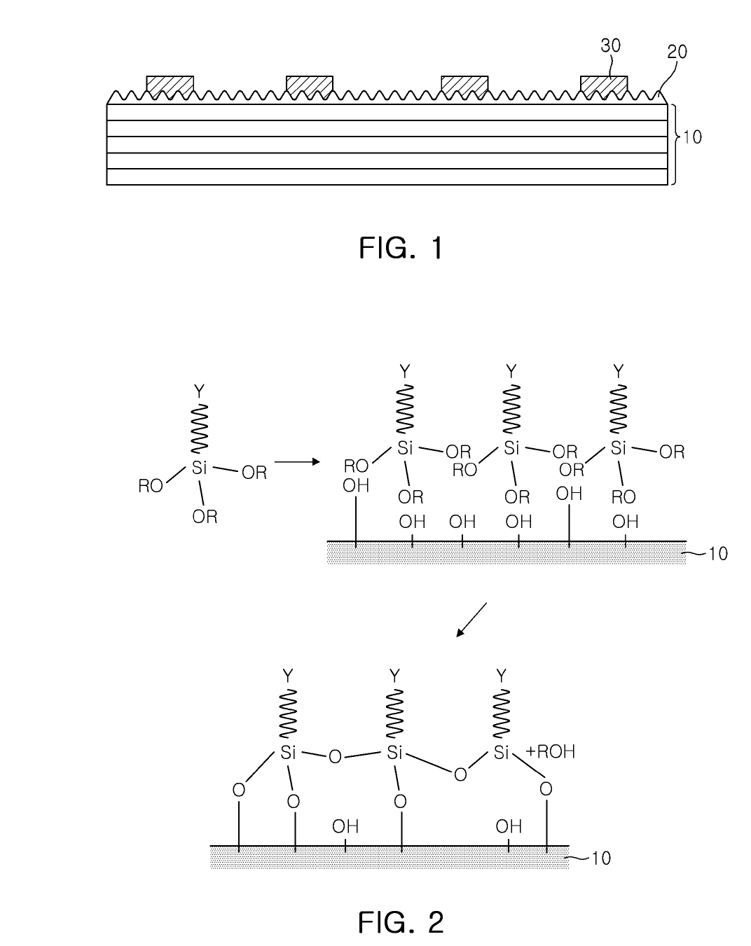

FIG. 1 is a cross-sectional diagram schematically showing a solar cell according to one embodiment of the present invention.

Referring to FIG. 1, a solar cell according to the present exemplary embodiment is configured to include a solar cell unit 10 absorbing sunlight to generate electricity, a surface treatment layer 20 formed on an upper surface of the solar cell, and an electrode layer 30 formed on the surface treatment layer.

The solar cell unit 10 absorbing sunlight to generate electricity is not particularly limited, and may be an inorganic solar cell or an organic solar cell according to a material a light absorbing layer is comprised of.

The inorganic solar cell may be, for example, a silicon solar cell, a compound solar cell; however, the inorganic solar cell is not limited thereto.

The silicon solar cell may be, for example, a monocrystalline silicon solar cell, a polycrystalline silicon solar cell, an amorphous silicon solar cell, or a monocrystalline and amorphous mixed silicon solar cell; however, the silicon solar cell is not limited thereto.

The compound semiconductor solar cell may be, for example, a CuInSe₂ solar cell (CIGS cell), a CuCaInSe₂ solar cell (CIGS cell), a GaAs solar cell, or a CdTe solar cell; however, the compound semiconductor solar cell is not limited thereto.

Further, the organic solar cell may be, for example, a dye-sensitized solar cell or a glass/polymer solar cell; however, the organic solar cell is not limited thereto.

The solar cell unit 10 according to the present exemplary embodiment may include a protective layer formed on the light absorbing layer, a back reflective electrode film, a front reflective electrode film, or the like.

The protective layer may be formed on an upper surface and a lower surface of the light absorbing layer to improve efficiency of the solar cell. The protective layer may be made of SiOₓ or SiOxN_{y}; however, a material of the protective layer is not limited thereto.

The back reflective electrode film may be formed on a lower surface of the light absorbing layer, and may reflect inputted sunlight to increase light efficiency and electrical conductivity. The back reflective electrode film may be made of indium tin oxide (ITO) or ZnO:Al.

The front reflective electrode film may be formed on an upper layer of the light absorbing layer, and prevent the inputted sunlight from being reflected to increase the efficiency of the solar cell. The front reflective electrode film may be made of indium tin oxide (ITO).

Although the present embodiment shows a case in which the surface treatment layer 20 is formed on the upper surface of the solar cell unit 10, the present invention is not limited thereto. The surface treatment layer 20 may also be formed on a lower surface of the solar cell unit 10, and a lower surface electrode may be formed on the surface treatment layer.

The surface treatment layer 20 may be formed by the condensation reaction of a compound having a functional group Y having a lone pair and an alkoxy group —OR.

The functional group Y, which has lone pair capable of being bonded to a metal, may be a functional group such as an amino group, a mercapto group, an imidazole group, or the like; however, the functional group is not limited thereto.

The functional group Y may be bonded to a metal of a metal electrode layer to increase a bonding force of the metal electrode layer.

In addition, the alkoxy group —OR may be an alkoxy group having a carbon number of 1 to 8; however, the alkoxy group is not limited thereto. The alkoxy group, which is bonded to the solar cell unit, may relatively easily form chemical bonding with a hydroxyl group —OH formed on the surface of the solar cell unit.

The compound having the functional group Y and the alkoxy group may be, for example, Y—Si—(OR)₃, Y—Zr—(OR)₃, Y—Ti—(OR)₃ or Y—Al—(OR)₂; however, the compound is not limited thereto.

As the Y—Si—(OR)₃, there are, for example, (3-Aminopropyl)triethoxysilane, N-(3-triethoxysilylpropyl)-4,5-dihydroimidazole, 3-(2-aminoethylamino) propyltrimethoxysilane, 3-(2-aminoethylamino) propyltriethoxysilane, mercaptopropyl-trimethoxysilane, mercaptopropyl-triethoxysilane, and the like; however, the Y—Si—(OR)₃ is not limited thereto.

FIG. 2 is a mimetic diagram schematically showing a forming process of a surface treatment layer according to an exemplary embodiment of the present invention.

Referring to FIG. 2, the condensation reaction of the compound Y—Si—(OR)₃ having the functional group Y having lone pair and the alkoxy group —OR is performed on one surface of the solar cell unit 10 to form a surface treatment layer having a silane bonding.

The Y—Si—(OR)₃ is unstable in the air and thus, the alkoxy group —OR may be substituted for the hydroxyl group —OH by hydrolysis. Chemical bonding with the hydroxyl group —OH existing on the surface of the solar cell unit 10 may be formed, simultaneously with forming the silane bonding, by the condensation reaction between the hydroxyl groups and the condensation reaction between the alkoxy groups.

One surface of the solar cell unit may be the front reflective preventing film or the light absorbing layer; however, one surface of the solar cell unit is not limited thereto.

In addition, treatment for activating the hydroxyl group may be performed on at least one of the upper and lower surfaces of the solar cell unit.

According to an exemplary embodiment of the present invention, the surface treating surface 20 may be a monomolecular layer formed by a self assembly monolayer.

The surface treatment layer 20 formed of the monomolecular layer has a relatively thin thickness to not deteriorate the optical characteristics of the solar cell.

According to the present exemplary embodiment, the metal electrode layer 30 may be formed on the surface treatment layer 20, and may be bonded to the functional group Y of the surface treatment layer. The functional group Y, which has lone pair, has an excellent bonding force with the metal.

The metal electrode layer 30 may be made of a metal paste including metal nanoparticles or metal microparticles. The metal may be Ag, Au, Cu, Ni, and the like.

The bonding force between the metal electrode layer and the solar cell unit is an important factor to increase the efficiency of the solar cell by determining ohmic contact.

In some companies, a paste having excellent adhesion has been developed in order to increase the bonding force between the metal electrode and the solar cell unit.

Generally, an additive such as an organic binder, an inorganic binder, or the like, may be used in order to increase the adhesion during mixing of the metal paste. However, the additive remains in the metal electrode after being sintered to deteriorate electrical characteristics and the efficiency of the solar cell.

However, according to the present exemplary embodiment, the surface treating surface made of a material having affinity with the metal electrode is formed on the solar cell unit to increase the bonding force between the solar cell unit and the metal electrode. The contact resistance is lowered through increase in the bonding force, thereby improving the efficiency of the solar cell. In addition, the surface treatment layer according to the exemplary embodiment of the present invention does not deteriorate light transmissivity.

Generally, the metal electrode layer made of metal paste may be contracted, while being subject to a sintering process. However, according to the exemplary embodiments of the present invention, the metal paste is strongly bonded to the surface treatment layer during the sintering of the metal paste to prevent contraction in a horizontal direction, thereby preventing deformation of the metal electrode layer. In addition, movement of the used nanoparticle of the metal paste is prevented during a drying process of the metal electrode layer.

Hereinafter, a method of manufacturing a solar cell according to an exemplary embodiment of the present invention will be described.

First, solar cell unit absorbing sunlight to generate electricity is prepared, and surface treatment layer is formed on at least one of the upper and lower surfaces of the solar cell unit.

The surface treatment layer may be formed using compound having functional group —Y having lone pair and alkoxy group —OR. The compound may be as described above, Y—Si—(OR)₃, Y—Zr—(OR)₃, Y—Ti—(OR)₃ or Y—Al—(OR)₂.

At this time, a portion of the alkoxy group —OR of the compound may be condensation reacted and other portion thereof may be reacted with hydroxyl group, whereby the surface treatment layer may be formed on one surface of the solar cell unit.

The surface treatment layer may be formed by a self-assembly monolayer, a Langmuir-Blodgett (LB) method, a Langmuir Schaefer (LS) method, a dip coating method, or a spin coating method; however, the method of forming the surface treatment layer is not limited thereto.

The method of self-assembly monolayer may be performed by preparing solution including the compound having the functional group having the lone pair and the alkoxy group, and immersing the solar cell unit in the solution. Concentration of the solution may be 0.001 to 0.1M, a solvent of the solution may be an organic solvent such as ethanol, methanol, toluene, or the like, and the immersing time may be 5 to 60 minutes, without being limited thereto.

In addition, treatment for activating the hydroxyl group may be performed on at least one of the upper and lower surfaces of the solar cell unit.

Then, the metal electrode layer may be formed on the surface treatment layer. According to the present exemplary embodiment, the metal electrode layer 30 may be formed on the surface treatment layer 20, and may be bonded to the functional group Y of the surface treatment layer. The functional group Y, which has the lone pair, has excellent bonding force with the metal.

The metal electrode layer 30 may be made of the metal paste including metal nanoparticles or metal microparticles. The metal may be Ag, Au, Cu, Ni, and the like.

The metal electrode layer 30 may be formed by a screen printing method, a gravure printing method, a flexographic printing method, an offset printing method, an inkjet printing method, or a roll-to-roll printing method.

Then, the metal electrode layer 30 is sintered to manufacture the solar cell.

Hereinafter, although the present invention will be described in detail through Inventive Example and Comparative Example, this description is to help a specific understanding of the present invention, and a scope of the present invention is not limited to Inventive Example.

According to Inventive Example, surface treatment layer made of amino silane was formed on the solar cell unit on which the front reflective preventing film made of ITO was formed, and then metal electrode layer was formed by a screen printing method using a copper paste and was then fired to manufacture solar cell.

In addition, according to Comparative Example, metal electrode layer was formed on front reflective preventing film made of ITO by a screen printing method using a copper paste without forming the surface treatment layer to manufacture the solar cell.

1) Energy Conversion Efficiency

As a result of inspecting optical characteristics of the solar cells according to Inventive and Comparative Examples, the energy conversion efficiency of the solar cells according to Inventive Example was 18.6%, and the energy conversion efficiency of the solar cells according to Comparative Example was 18.1%. Therefore, the energy conversion efficiency of the solar cell according to Inventive example was improved by 0.5%, as compared to that of the solar cell according to Comparative Example.

2) Bonding Force and Resistance Characteristics

In order to test the bonding force of the solar cells according to Inventive and Comparative Examples, a tape test was performed and resistance was measured.

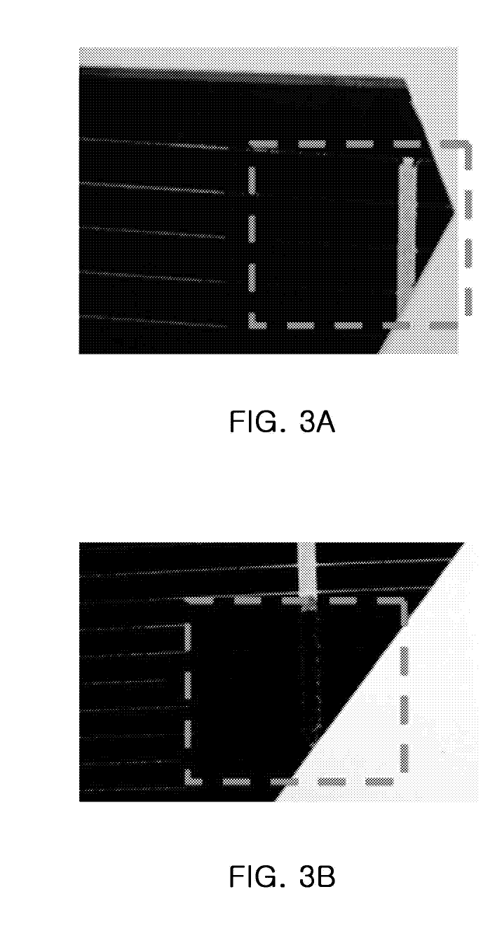

FIGS. 3A and 3B are, respectively, photographs of a surface of the solar cell formed by forming the metal electrode layer without forming the surface treatment layer and then sintering the metal electrode layer at 200° C. for 30 minutes and 60 minutes, respectively, according to Comparative Example.

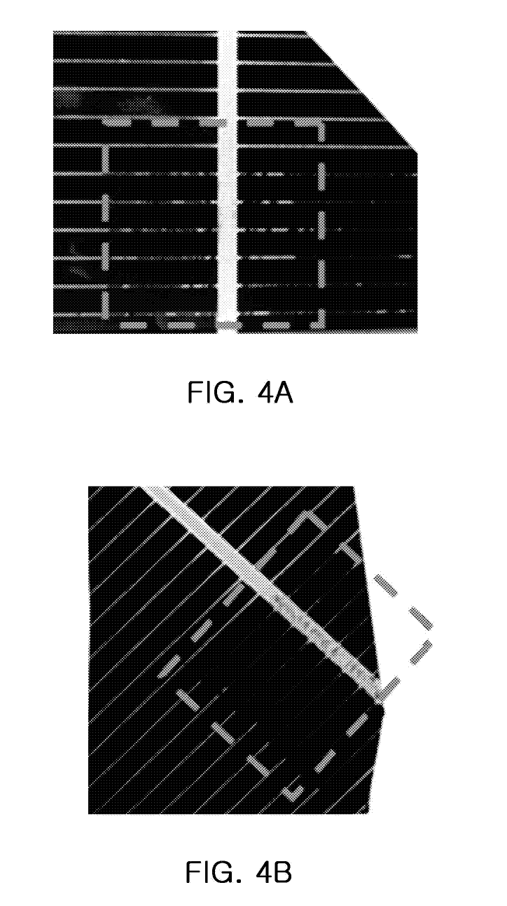

FIGS. 4A and 4B are, respectively, photographs of the surface of the solar cell formed by forming the surface treatment layer, forming the metal electrode layer, and then sintering the metal electrode layer at 200° C. for 30 minutes and 60 minutes, respectively, according to Inventive Example.

In addition, according to Comparative Example, the resistances of the solar cell sintered at 200° C. for 30 minutes and 60 minutes were 29 Ω/M and 8.5 Ω/M, respectively, and according to Inventive Example, the resistances of the solar cell sintered at 200° C. for 30 minutes and 60 minutes were 28 Ω/M and 8.9 Ω/M, respectively.

Referring to FIGS. 3A, 3B, 4A and 4B, as a result of the tape test in the case of the solar cells sintered at 200° C. for 30 minutes, a difference in loss of the metal electrode layer was not large between the inventive example and the comparative example; however, as a result of the tape test in the case of the solar cells sintered at 200° C. for 60 minutes, a loss of the metal electrode layer was large in the comparative example.

3) Contraction Characteristics

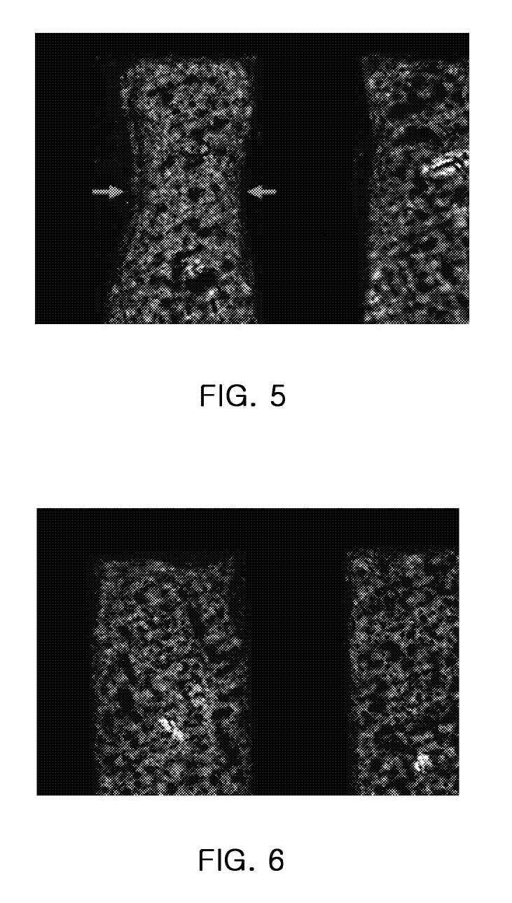

FIG. 5 is a photograph of the surface of the solar cell sintered at 200° C. for 60 minutes according to Comparative Example, and FIG. 6 is a photograph of the surface of the solar cell sintered at 200° C. for 60 minutes according to Inventive Example.

Referring to FIG. 5, it may be appreciated that the copper nanoparticle was contracted, while being subject to the sintering process. However, referring to FIG. 6, it may be confirmed that in the solar cell according to the embodiment of the present invention, the metal paste was strongly bonded to the surface treatment layer during the sintering of the metal paste, such that contraction was generated vertically but was scarcely generated horizontally.

4) Spreadability Control

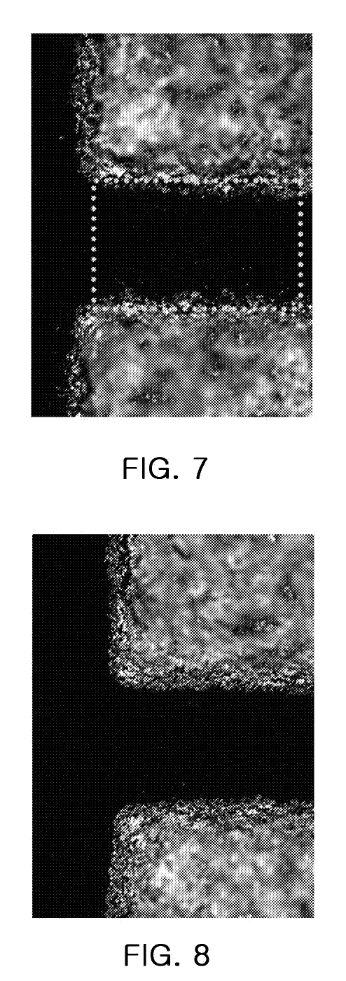

FIG. 7 is a photograph of the surface of the solar cell sintered at 200° C. for 60 minutes according to Comparative Example, and FIG. 8 is a photograph of the surface of the solar cell sintered at 200° C. for 60 minutes according to Inventive Example.

Referring to FIGS. 7 and 8, in the case of the solar cell according to Comparative Example, a solvent of paste has moved in an undesired direction during a drying process thereof, such that the nanoparticle used in the metal paste has been spread. However, referring to FIG. 8, it may be confirmed that the nanoparticles have scarcely moved, such that the spreadability was controlled.

5) Change in Optical Characteristics (Light Transmissivity Measurement)

Light transmissivities of the solar cells according to Comparative Example and Inventive Example were measured and the measurement results were shown in Table 1.

TABLE 1

| Inventive | Light | Comparative | Light |
|---|---|---|---|
| Example | Transmissivity | Example | Transmissivity |
| 1 | 83.55 | 1 | 83.60 |
| 2 | 83.56 | 2 | 83.61 |
| 3 | 83.49 | 3 | 83.63 |
| 4 | 83.60 | 4 | 83.65 |
| 5 | 83.60 | 5 | 83.58 |
| 6 | 83.63 | 6 | 83.59 |
| Average | 83.57 | Average | 83.61 |

Referring to Table 1, it may be appreciated that although the surface treatment layer according to Inventive Example is formed, the light transmissivity was not deteriorated.

As set forth above, according to the exemplary embodiments of the present invention, bonding force between the metal electrode and the solar cell unit may be increased by the surface treatment layer formed in the solar cell unit. The bonding force is increased to reduce contact resistance, whereby the efficiency of the solar cell may be improved. In addition, the surface treatment layer according to the exemplary embodiments of the present invention does not deteriorate light transmissivity.

Further, according to the exemplary embodiments of the present invention, the metal paste is strongly bonded to the surface treatment layer during the sintering of the metal paste to prevent contraction in a horizontal direction, thereby preventing deformation of the metal electrode layer. Furthermore, the movement of the used nanoparticles of the metal paste is prevented during a drying process of the metal electrode layer, whereby spreadability of the metal electrode layer may be controlled.

While the present invention has been shown and described in connection with the exemplary embodiments, it will be apparent to those in the art that modifications and variations can be made without departing from the spirit and scope of the invention as defined by the appended claims. Accordingly, various substitution, modifications and alteration may be made within the scope of the present invention may be made by those skilled in the art without departing from the spirit of the prevent invention defined by the accompanying claims.

What is claimed is:

1. A solar cell, comprising:
a solar cell unit absorbing sunlight to generate electricity;
a surface treatment layer formed on at least one of upper and lower surfaces of the solar cell unit by a condensation reaction of a compound having a functional group —Y having a lone pair and an alkoxy group —OR; and
a metal electrode layer bonded to the functional group —Y having the lone pair of the surface treatment layer.

2. The solar cell of claim 1, wherein the surface treatment layer is formed by a chemical bond of a hydroxyl group —OH existing on one surface of the solar cell unit and the alkoxy group —OR.

3. The solar cell of claim 1, wherein the functional group —Y having the lone pair is an amino group, a mercapto group, an imidazole group.

4. The solar cell of claim 1, wherein the alkoxy group —OR is an alkoxy group having a carbon number of 1 to 8.

5. The solar cell of claim 1, wherein the compound having the functional group —Y having the lone pair and the alkoxy group —OR is Y—Si—(OR)₃, Y—Zr—(OR)₃, Y—Ti—(OR)₃ or Y—Al—(OR)₂.

6. The solar cell of claim 1, wherein treatment for activating the hydroxyl group is performed on at least one of the upper and lower surfaces of the solar cell unit.

7. The solar cell of claim 1, wherein the surface treatment layer is a monomolecular layer.

8. The solar cell of claim 1, wherein the solar cell unit includes a light absorbing layer made of a monocrystalline silicon, a polycrystalline silicon, an amorphous silicon, or a mixture of a monocrystalline silicon and an amorphous silicon, CuInSe₂, CuCaInSe₂, GaAs, or an organic material.

9. The solar cell of claim 1, wherein the metal electrode layer is made of a metal paste.

10. The solar cell of claim 1, wherein the solar cell unit includes at least one of a back reflective electrode film and a front reflective electrode film.

11. A method of manufacturing a solar cell, comprising:
preparing a solar cell unit absorbing sunlight to generate electricity;
forming a surface treatment layer on at least one of upper and lower surfaces of the solar cell unit by a condensation reaction of a compound having a functional group —Y having a lone pair and an alkoxy group —OR; and
forming a metal electrode layer on the surface treatment layer.

12. The method of manufacturing a solar cell of claim 11, wherein the surface treatment layer is formed by a chemical bond of a hydroxyl group existing on one surface of the solar cell unit and an alkoxy group.

13. The method of manufacturing a solar cell of claim 11, wherein the surface treatment layer is formed by a self-assembly monolayer, a Langmuir-Blodgett (LB) method, a Langmuir Schaefer (LS) method, a dip coating method, or a spin coating method.

14. The method of manufacturing a solar cell of claim 11, wherein the surface treating surface is a monomolecular layer formed by a self assembly monolayer.

15. The method of manufacturing a solar cell of claim 11, wherein the functional group —Y having the lone pair is an amino group, a mercapto group, an imidazole group.

16. The method of manufacturing a solar cell of claim 11, wherein the alkoxy group —OR is an alkoxy group having a carbon number of 1 to 8.

17. The method of manufacturing a solar cell of claim 11, further comprising, before the forming of the surface treatment layer, performing treatment for activating the hydroxyl group on at least one of the upper and lower surfaces of the solar cell unit.

18. The method of manufacturing a solar cell of claim 11, wherein the compound having the functional group —Y having the lone pair and the alkoxy group —OR is Y—Si—(OR)₃, Y—Zr—(OR)₃, Y—Ti—(OR)₃ or Y—Al—(OR)₃.

19. The method of manufacturing a solar cell of claim 11, wherein the metal electrode layer is made of a metal paste.

20. The method of manufacturing a solar cell of claim 11, wherein the metal electrode layer is formed by a screen printing method, a gravure printing method, a flexographic printing method, an offset printing method, an inkjet printing method, or a roll-to-roll printing method.
